(19) United States
(12) Patent Application Publication
(10) Pub. No.: US 2008/0217643 A1
(43) Pub. Date: Sep. 11, 2008

(54) Light-emitting diode and heat radiating unit therefor

(76) Inventors: Chung Yiu Lin, Taipei City (TW); Yong Tai Chen, Keelung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/714,831

(22) Filed: Mar. 7, 2007

(51) Int. Cl. H01L 33/00

(52) U.S. Cl. 257/99; 257/E33.056

(57) ABSTRACT

A light-emitting diode (LED) is mounted on a heat radiating unit therefor. The LED includes a metal carrier having two through holes, and a light-emitting chip packaged on the metal carrier and having a positive and a negative pin fixed to and insulated from the through holes by sintered glass. The heat radiating unit includes a seat and a hold-down plate closed onto a top of the seat. The seat is formed with a plurality of cavities and provided at an underside with a plurality of radiating fins; the hold-down plate is formed with a plurality of openings corresponding to the cavities on the seat. The LED is mounted in the cavity to expose to external space via the openings on the hold-down plate. Heat produced by the LED during working is transferred via the metal carrier to the heat radiating unit and radiated quickly.

### FIELD OF THE INVENTION

The present invention relates to a light-emitting diode (LED) and heat radiating unit therefor, and more particularly to an LED mounted on a heat radiating unit that enables good radiating of heat produced by the LED to prolong the service life of the LED.

### BACKGROUND OF THE INVENTION

FIG. 1 shows a general light-emitting diode (LED), which includes an LED main body 1 and a circuit board 2. The LED main body 1 is packaged on a seat 11, from which leads 12 are extended. A heat radiating layer 13 is provided at a bottom of the seat 11. The circuit board 2 is made of an aluminum material with contacts 21 provided thereon. The LED main body 1 is connected to the circuit board 2 by soldering the leads 12 to the contacts 21. When the LED main body 1 is lightened, heat is produced and transferred from the leads 12 to the circuit board 2 via the heat radiating layer 13, and is finally radiated from the circuit board 2. The above-structured LED has a relatively small heat radiating area and accordingly, low heat radiating rate and poor heat radiating effect to largely reduce the service life of the LED. It is therefore tried by the inventor to develop an improved LED and heat radiating unit therefor, so as to make the LED more practical for use.

### SUMMARY OF THE INVENTION

A primary object of the present invention is to provide an LED and a heat radiating unit therefor, so that heat produced by the LED during working is effectively radiated via the heat radiating unit, allowing the LED to have prolonged service life.

To achieve the above and other objects, the light-emitting diode (LED) of the present invention includes a metal carrier provided within a central area thereof with two axially extended through holes; and a light-emitting chip packaged on a top of the metal carrier with a positive pin and a negative pin separately extended through the two through holes. The two pins are fixed to and insulated from the through holes by sintered glass. Heat produced by the LED during working is radiated via the metal carrier.

The heat radiating unit for the LED of the present invention includes a seat and a hold-down plate closed onto a top recess of the seat. The seat is formed with a plurality of cavities and provided at an underside with a plurality of radiating fins. The hold-down plate is formed with a plurality of openings corresponding to the cavities on the seat. The LED is mounted in the cavity to expose to external space via the openings on the hold-down plate. Heat produced by the LED during working is transferred via the metal carrier to the heat radiating unit and radiated quickly.

The metal carrier of the LED is provided near one side of the light-emitting chip with a fixing hole corresponding to one of a positive pin and a negative pin of the light-emitting chip. And, each of the cavities on the seat of the heat radiating unit is provided with a post. When the metal carrier of the LED is mounted in the cavity, the fixing hole is engaged with the post to hold the LED in the cavity and enable easy distinguishing of the positive pin from the negative pin.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of a conventional light-emitting diode;

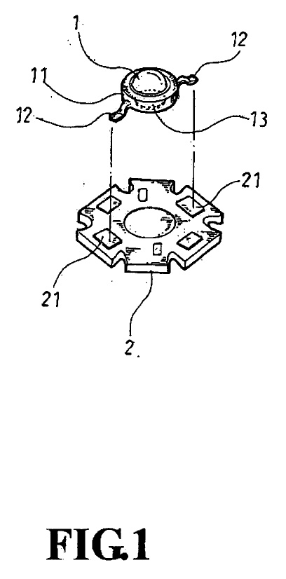

FIGS. 2 and 3 are top and bottom perspective views, respectively, of a light-emitting diode according to the present invention;

FIG. 4 is an exploded perspective view of a heat radiating unit according to the present invention for use with the light-emitting diode of FIGS. 2 and 3;

FIGS. 5 and 6 are assembled front and end sectional views of FIG. 4;

FIG. 7 is an assembled view of FIG. 4; and

FIG. 8 is a bottom view of FIG. 7.

### DETAILED DESCRIPTION OF THE PREFERRED EMBODIMENTS

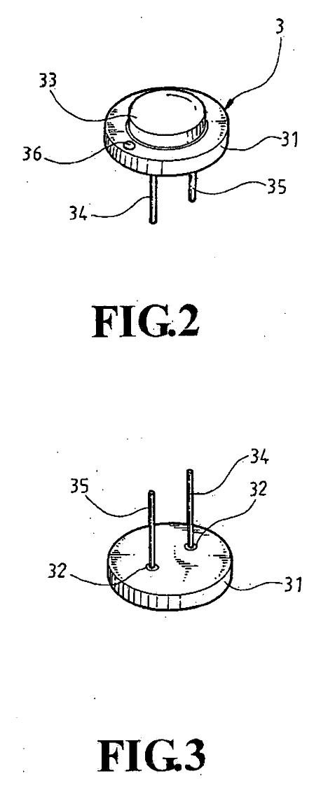

Please refer to FIGS. 2 and 3 that are top and bottom perspective views, respectively, of a light-emitting diode (LED) 3 according to the present invention. As shown, the LED 3 includes a metal carrier 31 provided within a central area thereof with two axially extended through holes 32; and a light-emitting chip 33 packaged on a top of the metal carrier 31 with a positive pin 34 and a negative pin 35 separately extended through the two through holes 32. The pins 34, 35 are fixed to and insulated from the through holes 32 by sintered glass. The metal carrier 31 is provided near one side of the light-emitting chip 33 with a fixing hole 36, such that the fixing hole 36 is aligned with and closer to either the positive pin 34 or the negative pin 35. Heat produced by the light-emitting chip 33 during working may be radiated via the metal carrier 31.

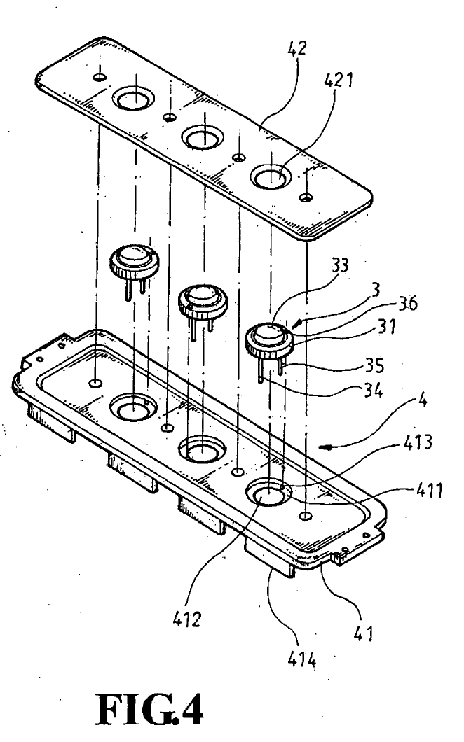

Please refer to FIG. 4 that is an exploded perspective view of a heat radiating unit 4 according to the present invention for use with the LED 3. As shown, the heat radiating unit 4 includes a seat 41 and a hold-down plate 42 fitly mounted to a top recess of the seat 41. The seat 41 is formed at predetermined positions with a plurality of cavities 411, each of which has a central opening 412 defined therein. An upward extended post 413 is provided in each of the cavities 411 to correspond to the fixing hole 36 on the metal carrier 31 of the light-emitting diode 3. The seat 41 is provided at an underside with a plurality of spaced radiating fins 414. The hold-down plate 42 has a size substantially the same as that of the top recess of the seat 41, and is provided with a plurality of openings 421 corresponding to the cavities 411 on the seat 41.

The light-emitting diode 3 is firmly mounted on the seat 41 of the heat radiating unit 4 with the metal carrier 31 seated in one cavity 411 and the fixing hole 36 engaged with the post 413. With the fixing hole 36 provided near one of the positive and the negative pin 34, 35, it is very easy to distinguish the positive pin 34 from the negative pin 35 via the engaged fixing hole 36 and post 413 when the LED 3 has been assembled to the cavity 411. When all the cavities 411 have an LED 3 mounted therein, the hold-down plate 42 is closed onto the seat 41. At this point, the LEDs 3 are exposed to an external space via the openings 421. In this manner, the heat radiating unit 4 is associated with the LEDs 3 for radiating heat produced by the LEDs 3 during working.

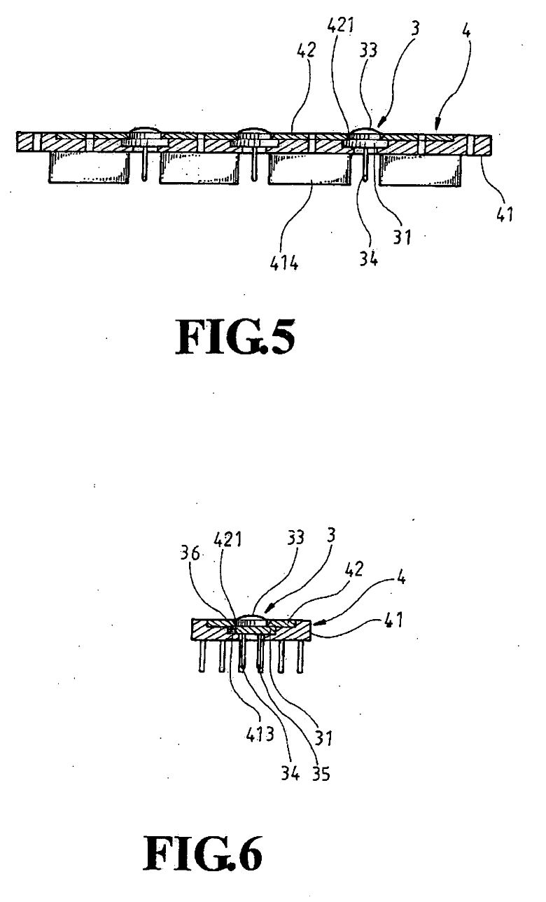

Please refer to FIGS. 5 and 6 that are front and end sectional views, respectively, of the assembled LEDs 3 and heat radiating unit 4. As shown, the metal carriers 31 of the LEDs 3 are separately seated in the cavities 411 on the seat 41 with the fixing holes 36 on the metal carriers 31 engaged with the posts 413 in the cavities 411. Moreover, the positive and the negative pins 34, 35 of the LEDs 3 are downward extended through the central openings 412 of the cavities 411 to project from the underside of the seat 41 for welding to a circuit board (not shown), and the hold-down plate 42 is closed onto the top recess of the seat 41. Heat produced by the LEDs 3 during working is transmitted via the metal carriers 31 to the heat radiating unit 4 and radiated to provide an excellent heat radiating effect.

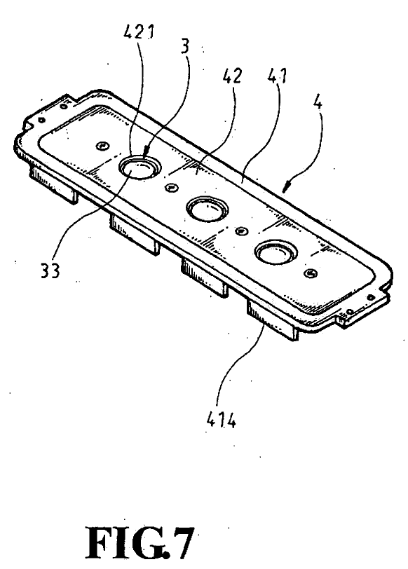

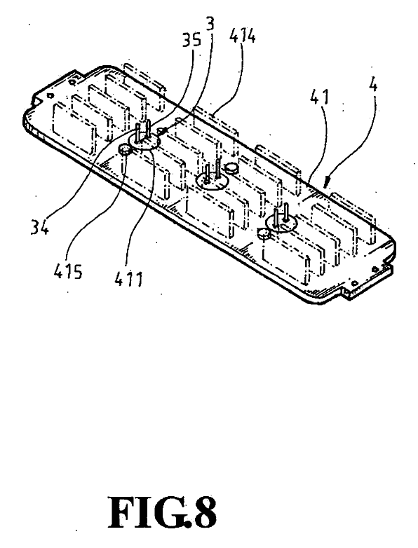

FIGS. 7 and 8 are top and bottom perspective views, respectively, of the LEDs 3 and the heat radiating unit 4 of the present invention in an assembled state. As shown, the LEDs 3 are exposed to an external space via the openings 421 on the hold-down plate 42, so that an illuminating effect is provided when the LEDs 3 are lightened. The heat radiating unit 4 with the radiating fins 414 provided at the underside thereof enables radiating of heat at high efficiency to thereby largely reduce the working temperature and prolong the service life of the LEDs 3. Moreover, please refer to FIGS. 8 and 4 at the same time, the seat 41 may be provided on the underside near each of the cavities 411 with a round post 415 corresponding to the upward extended post 413 in the cavity 411, so as to enable easy distinguishing of the positive pins 34 from the negative pins 35 and facilitate correct connecting of the pins 34, 35 to the circuit board.

With the above arrangements, heat produced by the LEDs 3 during working may be highly efficiently radiated via the metal carriers 31 and the heat radiating unit 4 assembled to the LEDs 3, allowing the LEDs 3 to have increased service life.

What is claimed is:

1. A light-emitting diode, comprising a metal carrier having two axially extended through holes provided within a central area thereof, and a light-emitting chip packaged on a top of the metal carrier with a positive pin and a negative pin of the light-emitting chip separately downward extended through the two through holes on the metal carrier; wherein the positive and negative pins are fixed to and insulated from the through holes by sintered glass.

2. A heat radiating unit for light-emitting diode, comprising a seat and a hold-down plate for closing onto a top recess of the seat; the seat being provided at predetermined positions with a plurality of cavities, each of which defining a central opening therein and having a light-emitting diode mounted therein, and at an underside with a plurality of downward extended radiating fins; and the hold-down plate having a size similar to that of the top recess of the seat, and being provided with a plurality of openings corresponding to the cavities on the seat.

3. The light-emitting diode as claimed in claim 1, wherein the metal carrier is provided near one side of the light-emitting chip with a fixing hole, such that the fixing hole is aligned with and closer to one of the positive and the negative pin to enable easy distinguishing of the positive pin from the negative pin.

4. The heat radiating unit for light-emitting diode as claimed in claim 2, wherein the light-emitting diode includes a metal carrier having a fixing hole provided at a predetermined position thereof to align with and locate close to one of a positive and a negative pin of a light-emitting chip packaged on a top of the metal carrier, and each of the cavities on the seat is provided with an upward extended post corresponding to the fixing hole on the metal carrier, such that the light-emitting diode is mounted on the seat in the cavity with the fixing hole on the metal carrier engaged with the post on the cavity.

5. The heat radiating unit for light-emitting diode as claimed in claim 4, wherein the seat is provided on the underside near each of the cavities with a round post corresponding to the upward extended post in the cavity for easily distinguishing the positive pin from the negative pin of the light-emitting diode to facilitate correct connection of the two pins to a circuit board.
